(19) United States
(12) Patent Application Publication
(10) Pub. No.: US 2011/0032956 A1
(43) Pub. Date: Feb. 10, 2011

(54) WIDE TEMPERATURE RANGE (WiTR) OPERATING WAVELENGTH-NARROWED SEMICONDUCTOR LASER

(75) Inventor: Manoj Kanskar, Madison, WI (US)

Correspondence Address: FULBRIGHT & JAWORSKI L.L.P.;Attn: MN IP Docket, 600 Congress Avenue, Suite 2400, Austin, TX, 78701, US

(73) Assignee: ALFALIGHT

(21) Appl. No.: 12/843,508

(22) Filed: Jul. 26, 2010

Related U.S. Application Data
(60) Provisional application No. 61/231,602, filed on Aug. 5, 2009.

(51) Int. Cl. H01S 5/06; H01S 5/343

(52) U.S. Cl. 372/20; 372/45.01; 372/50.11; 977/755; 977/773; 977/951

(57) ABSTRACT

The present invention provides a wide temperature range (WiTR) operating wavelength-narrowed and wavelength-stabilized semiconductor laser having a wide bandwidth gain medium imbedded in a waveguide layer comprising a plurality of quantum dots or quantum wells wherein each quantum dot or quantum well has a different gain peak-wavelength that provides gain at different temperatures as the junction temperature of the laser changes. Therefore, the wavelength defined by an appropriate grating to lock the wavelength and narrow the emission-bandwidth can be realized over a much wider operating temperature range than possible with gain medium that comprises just single quantum well or quantum dot or a plurality of quantum wells or quantum dots that have the same gain peak-wavelength.

### CROSS REFERENCE TO RELATED APPLICATIONS

This application claims benefit under 35 U.S.C. §119(e) to U.S. Ser. No. 61/231,602, entitled “WIDE TEMPERATURE RANGE (WiTR) OPENING WAVELENGTH-NARROWED SEMICONDUCTOR LASER”, filed Aug. 5, 2009 (attorney docket number ALFA-021/PROV) the contents of which are incorporated herein by reference in their entirety.

### FIELD OF THE INVENTION

The invention relates to a linewidth narrowed and wavelength stabilized semiconductor laser that has a wide range of operating temperature due to wide gain bandwidth and a wavelength locking and narrowing mechanism.

### BACKGROUND OF THE INVENTION

In an external-cavity wavelength-locked and linewidth-narrowed semiconductor laser such as external grating-stabilized, volume Bragg grating stabilized or fiber Bragg grating stabilized, to name a few; or grating-integrated semiconductor lasers such as distributed feedback (DFB) laser, distributed Bragg reflector (DBR) laser, surface-emitting distributed feedback (SE-DFB) laser, partial grating DFB laser (p-DFB), alpha-DFB laser or MOPA's (whether single or multi spatial mode), the emission wavelength is approximately locked at the Bragg resonance condition (Bragg resonance tunes only at approximately 0.07 nm/° C. for semiconductor gratings and less than that for external Bragg gratings) set by the internal grating pitch and the effective index of the lasing mode even though the semiconductor gain medium peak tunes at a rate of approximately 0.32 nm/° C. as the junction temperature changes (for semiconductor lasers fabricated on GaAs with emission wavelength in the range of 600 nm to 1600 nm). This is also true for tunable VCSELs since the “effective cavity length” of a VCSEL also tunes at approximately 0.07 nm/° C. and the gain peak tunes at 0.32 nm/° C. There is a similar relationship for longer wavelength semiconductor lasers of the aforementioned types that are usually fabricated on InP substrates and emits in the wavelength from 1200 nm to over 2000 nm. Since the gain peak tunes at nearly five times greater rate compared to the Bragg peak, there is a finite wavelength locking temperature range (usually a range in temperature of ΔT=25° C.) over which wavelength-locking operation is possible. Eventually, the gain peak drifts too far out of resonance with respect to the Bragg condition set by the wavelength-locking method and the wavelength-locking ceases. This makes it not feasible to use wavelength-locked semiconductor laser for many applications that require wide operating ambient temperature.

The most straight-forward method to overcome the temperature effect on the gain peak drift is to use multiple lasers, each designed to cover different temperature regimes. However, as can be appreciated, the use of multiple lasers is inefficient and costly since many more lasers have to be deployed depending on the total operating temperature range that needs to be covered. Another method is to keep the temperature of the junction of the laser at a constant temperature while the ambient temperature varies. This can be achieved by using cooling or heating methods such as a thermo-electric cooler, water chillers, heaters or fans, to name a few. These solutions add cost and complexity to the system and reduce overall efficiency due to additional components that has to be used to keep the junction temperature constant.

### SUMMARY OF THE INVENTION

The present invention provides a wide temperature range (WiTR) operating wavelength-narrowed and wavelength-stabilized semiconductor laser having a wide bandwidth gain medium imbedded in a waveguide layer comprising a plurality of quantum dots or quantum wells wherein each quantum dot or quantum well has a different gain peak-wavelength that provides gain at different temperatures as the junction temperature of the laser changes. Therefore, the wavelength defined by an appropriate grating to lock the wavelength and narrow the emission-bandwidth can be realized over a much wider operating temperature range than possible with gain medium that comprises just single quantum well or quantum dot or a plurality of quantum wells or quantum dots that have the same gain peak-wavelength.

Therefore, in one exemplary embodiment, the invention provides an ultra-wide gain bandwidth semiconductor laser comprising a wide gain medium in conjunction with a wavelength locking mechanism. In this embodiment, the emission wavelength of the gain medium is tuned with a change in temperature of the laser and the locking mechanism locks the wavelength over a wide range of temperature changes.

In some exemplary embodiments, the wide gain medium comprises a plurality of quantum wells or quantum dots each having a different peak gain-wavelength. Therefore, in these embodiments, as the temperature of the laser changes the gain provided by one or more different quantum wells or quantum dots provides photons near the wavelength of the laser that is locked by the locking mechanism, wherein a wide temperature operation with emission-bandwidth narrowed and wavelength-stabilized semiconductor laser is achieved.

In some exemplary embodiments, the wavelength locking and linewidth narrowing mechanism is a grating. In various exemplary embodiments, when the grating is an internal grating, the internal grating comprises a distributed feedback grating (DFB) or a distributed Bragg reflector (DBR) or a partial distributed feedback (p-DFB) grating. In various other exemplary embodiments, when the grating is an external grating, the external grating comprises a volume Bragg grating (VBG), and external fiber Bragg grating (FBG), or an external grating in an external cavity laser (ECL) configuration.

In yet other exemplary embodiments, the invention includes a wide temperature operating semiconductor laser comprising: multiple quantum wells or quantum dots each with different peak gain wavelength in conjunction with an internal grating or external grating to lock the wavelength to the emission-bandwidth narrowed spectrum over a wider operating temperature range than possible with just single peak gain-wavelength quantum well or quantum dot.

In these exemplary embodiments, when the wavelength locking and linewidth narrowing mechanism is a grating, the grating is an internal grating or an external grating. In various embodiment where the grating is an internal grating, the internal grating comprises a distributed feedback grating (DFB) or a distributed Bragg reflector (DBR) or a partial distributed feedback (p-DFB) grating. In various other exemplary embodiments, when the grating is an external grating, the external grating comprises a volume Bragg grating (VBG), and external fiber Bragg grating (FBG), or an external grating in an external cavity laser (ECL) configuration.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be apparent from the description, as set forth hereinafter.

### BRIEF DESCRIPTION OF THE FIGURES

Various exemplary embodiments of the compositions and methods according to the invention will be described in detail, with reference to the following figures wherein:

FIG. 1 is a schematic diagram of one exemplary embodiment of a WiTR operating wavelength-narrowed semiconductor laser according to the invention wherein the wavelength locking and linewidth-narrowing laser-comprises a DFB grating.

FIG. 2 is a schematic diagram of another exemplary embodiment of a WiTR operating wavelength-narrowed semiconductor laser according to the invention wherein the wavelength locking and linewidth-narrowing laser comprises a partial DFB (p-DFB) grating.

FIG. 3 is a schematic diagram of another exemplary embodiment of a WiTR operating wavelength-narrowed semiconductor laser according to the invention wherein the wavelength locking and linewidth-narrowing laser comprises DBR grating.

FIG. 4 is a schematic diagram of another exemplary embodiment of a WiTR operating wavelength-narrowed semiconductor laser according to the invention wherein the wavelength locking and linewidth-narrowing laser comprises an external volume Bragg grating (VBG).

FIG. 5 is a schematic diagram of another exemplary embodiment of a WiTR operating wavelength-narrowed semiconductor laser according to the invention wherein the wavelength locking and linewidth-narrowing laser comprises a an external fiber Bragg grating (FBG).

FIG. 6 is a schematic diagram of another exemplary embodiment of a WiTR operating wavelength-narrowed semiconductor laser according to the invention wherein the wavelength locking and linewidth-narrowing laser comprises an external grating and an output coupler.

FIG. 7 is a schematic diagram of another exemplary embodiment of a WiTR operating wavelength-narrowed semiconductor laser also known as the vertical-cavity surface emitting laser (VCSEL) according to the invention wherein the wavelength locking and linewidth-narrowing in the laser uses the method that comprises a short cavity that is a multiple of quarter the wavelength of light (multiple quarter-lambda's).

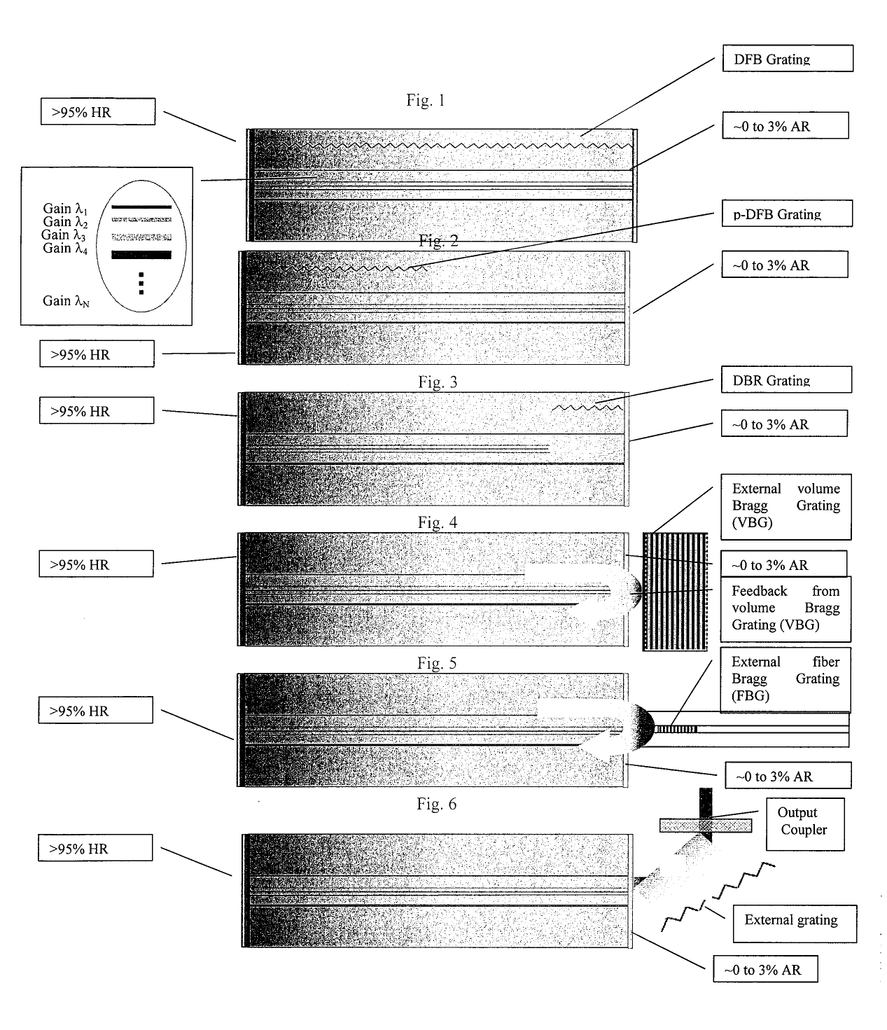

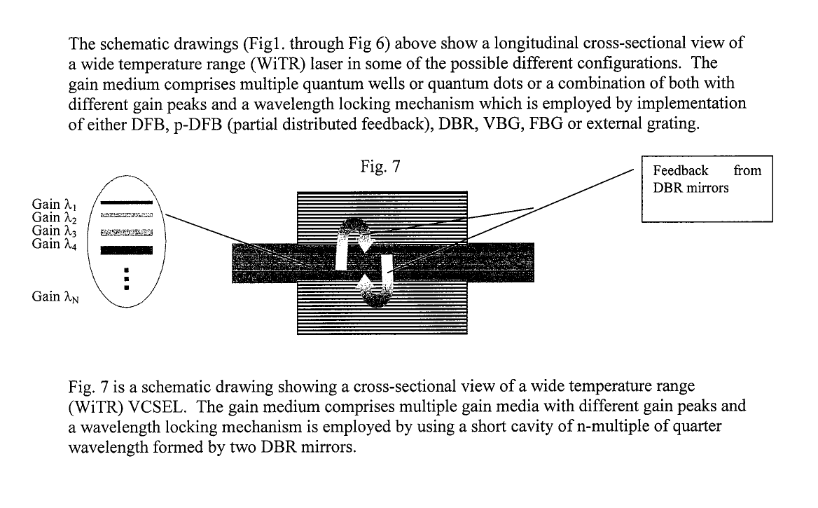

### DETAILED DESCRIPTION OF THE EXEMPLARY EMBODIMENTS

The present invention provides a wide temperature range (WiTR) operating wavelength-narrowed and wavelength-stabilized semiconductor laser having a wide bandwidth gain medium imbedded in a waveguide layer comprising a plurality of quantum dots or quantum wells wherein each quantum dot or quantum well has a different gain peak-wavelength that provides gain at different temperatures as the junction temperature of the laser changes. Therefore, the wavelength defined by an appropriate grating to lock the wavelength and narrow the emission-bandwidth can be realized over a much wider operating temperature range than possible with gain medium that comprises just single quantum well or quantum dot or a plurality of quantum wells or quantum dots that have the same gain peak-wavelength.

Therefore, in one exemplary embodiment, the invention provides a wide temperature operating wavelength-stabilized and linewidth-narrowed semiconductor laser comprising a wide gain medium in conjunction with a wavelength locking mechanism. In this embodiment, the emission wavelength of the gain medium is tuned with a change in temperature of the laser and the locking mechanism locks the wavelength over a wide range of temperature changes.

In some exemplary embodiments, the wide gain medium comprises a plurality of quantum wells or quantum dots each having a different peak gain-wavelength. Therefore, in these embodiments, as the temperature of the laser changes the gain provided by one or more different quantum wells or quantum dots provides photons near the wavelength of the laser that is locked by the locking mechanism, wherein a wide temperature operation with emission-bandwidth-narrowed and wavelength-stabilized semiconductor laser is achieved.

In some exemplary embodiments, the wavelength locking and linewidth narrowing mechanism is a grating. In various exemplary embodiments, when the grating is an internal grating, the internal grating comprises a distributed feedback grating (DFB) or a distributed Bragg reflector (DBR) or a partial distributed feedback (p-DFB) grating. In various other exemplary embodiments, when the grating is an external grating, the external grating comprises a volume Bragg grating (VBG), and external fiber Bragg grating (FBG), or an external grating in an external cavity laser (ECL) configuration.

In yet other exemplary embodiments, the invention includes a wide temperature operating semiconductor laser comprising: multiple quantum wells or quantum dots each with different peak gain wavelength in conjunction with an internal grating or external grating to lock the wavelength to the emission-bandwidth narrowed spectrum over a wider operating temperature range than possible with just single peak gain-wavelength quantum well or quantum dot.

The present invention provides tailored gain media with broader gain spectrum designed in such a way that gain media (comprised of multiple quantum wells or quantum dots) tuned to peak at different wavelengths for each quantum well or quantum dot resulting in a much wider total gain spectrum for the semiconductor laser. As a result, when a wavelength narrowing and locking method is used in conjunction with broader gain medium, the semiconductor laser operates with narrow spectrum over a temperature range that is numerous times greater than feasible with regular semiconductor lasers.

The number of quantum wells or dots is chosen to span the maximum operating temperature range required by the application.

The peak of the gain for each of the quantum wells is judiciously chosen in such a manner so that the widest operating temperature range could be achieved with a minimum number of quantum wells.

The gain peak for each of the quantum wells is also chosen in such a way that the location of these gain peaks reside at a shorter wavelength relative to the Bragg resonance peak (set by the grating in the DFB laser) specified at the lowest operating temperature. As a result, as the operating temperature rises towards the maximum operating temperature, the gain peaks tune at a rate of approximately 0.32 nm/° C., towards the longer wavelength thereby providing gain at the Bragg condition over the specified temperature range. This could be reversed to achieve wider temperature range in the cold direction as well.

The use of multiple quantum well each detuned from the Bragg wavelength and from each other at an interval makes it possible to use a single semiconductor laser to cover much wider operating temperature range than what is currently possible with either single quantum well or dot or multiple quantum wells or dots with the same gain peak.

### Example 1

### Fabrication of Multiple Quantum Wells with Varying Peak Gain-Wavelengths

Those of skill in the art will appreciate that the peak wavelength of the gain media can be accomplished by manipulating either the size of the quantum well or quantum dot and or the composition of the quantum well or quantum dot. For example, typical semiconductor materials and emission wavelengths of light-emitting diodes include but is not limited to those provided in table 1, below.

TABLE 1

| Material | Typical emission wavelengths | |
|---|---|---|
| InGaN/GaN, ZnS | 450-530 | nm |
| GaP:N | 565 | nm |
| AlInGaP | 590-620 | nm |
| GaAsP, GaAsP:N | 610-650 | nm |
| InGaAsP on GaAs | 660-890 | nm |
| InGaAs on GaAs | 870-1300 | nm |
| AlGaAsIn on GaAs | 680-860 | nm |
| InGaAsP on InP | 1000-2000 | nm |

### Example 2

### Exemplary Use of the WiTR

The present invention has many useful applications. For example, U.S. Provisional Patent Application 61/199,582 “Compact non-lethal optical disruption (NLOD) device” (Alfalight, Inc.) discloses a DFB laser comprising multiple different wavelength-stabilized and linewidth-narrowed diodes that are used to cover a wide operating temperature (greater than 25° C.). Each one has a gain medium (quantum well) that is designed to peak at several different wavelengths. The WiTR will allow the use of a single DFB laser to pump the Nd-doped vanadate and still achieve a wide operating temperature. In fact, in principle, this invention will allow unlimited operating temperature range. The ultimate limit will be determined by the efficiency of the semiconductor laser which will approach zero above 150° C. For example, the NLOD (ALFALIGHT™, Inc) currently uses two 808 nm DFB pump diodes to achieve 50° C. operating temperature range. This limitations is illustrated in FIG. 1 of Application No. 61/199,582). However, use of the instant WiTR invention will allow use of a single 808 nm DFB pump diode.

While this invention has been described in conjunction with the various exemplary embodiments outlined above, various alternatives, modifications, variations, improvements and/or substantial equivalents, whether known or that are or may be presently unforeseen, may become apparent to those having at least ordinary skill in the art. Accordingly, the exemplary embodiments according to this invention, as set forth above, are intended to be illustrative not limiting. various changes may be made without departing from the spirit and scope of the invention. therefor3e, the invention is intended to embrace all known or later-developed alternatives, modifications, variations, improvements and/or substantial equivalents of these exemplary embodiments.

What is claimed is:

1. An wide temperature operating semiconductor laser comprising:
a) a wide gain medium
b) a wavelength locking mechanism
wherein the emission wavelength of the gain medium is tuned with a change in temperature of the laser and the locking mechanism locks the wavelength over a wide range of temperature changes.

2. The wide temperature operating semiconductor laser of claim 1, wherein the wide gain medium comprises a plurality of quantum wells or quantum dots each having a different peak gain-wavelength and wherein as the temperature of the laser changes the gain provided by one or more different quantum wells or quantum dots provides photons near the wavelength of the laser that is locked by the locking mechanism, wherein a wide temperature operation with emission-bandwidth narrowed and wavelength-stabilized semiconductor laser is achieved.

3. The wide temperature operating semiconductor laser of claim 1, wherein the wavelength locking and linewidth narrowing mechanism is a grating.

4. The wide temperature operating semiconductor laser of claim 2, wherein the internal grating comprises a distributed feedback grating (DFB) or a distributed Bragg reflector (DBR) or a partial distributed feedback (p-DFB) grating.

5. The wide gain bandwidth semiconductor laser of claim 2, wherein the external grating comprises a volume Bragg grating (VBG), and external fiber Bragg grating (FBG), or an external grating in an external cavity laser (ECL) configuration.

6. A wide temperature operating semiconductor laser comprising: multiple quantum wells or quantum dots each with different peak gain wavelength in conjunction with an internal grating or external grating to lock the wavelength to the emission-bandwidth narrowed spectrum over a wider operating temperature range than possible with just single peak gain-wavelength quantum well or quantum dot.

7. The wide temperature operating semiconductor laser of claim 6, wherein the internal grating comprises a distributed feedback grating (DFB) or a distributed Bragg reflector (DBR) or a partial distributed feedback (p-DFB) grating.

8. The ultra-wide gain bandwidth semiconductor laser of claim 6, wherein the external grating comprises a volume Bragg grating (VBG), and external fiber Bragg grating (FBG), or an external grating in an external cavity laser (ECL) configuration.
